(19) United States
(12) Patent Application Publication
(10) Pub. No.: US 2025/0324656 A1
(43) Pub. Date: Oct. 16, 2025

(54) SEMICONDUCTOR DEVICE

(71) Applicant: DB HiTek Co., Ltd., Seoul (KR)

(72) Inventors: Seung Hyun KIM, Bucheon-si (KR); Hee Bae LEE, Bucheon-si (KR); Jae Yuhn MOON, Bucheon-si (KR); Gyu Hyun JUNG, Bucheon-si (KR); Soon Jong PARK, Bucheon-si (KR)

(73) Assignee: DB HiTek Co., Ltd., Seoul (KR)

(21) Appl. No.: 18/739,894

(22) Filed: Jun. 11, 2024

(30) Foreign Application Priority Data
Apr. 15, 2024 (KR) 10-2024-0050120

(51) Int. Cl. H01L 29/78; H01L 29/06; H01L 29/10

(52) U.S. Cl. CPC H10D 30/66; H10D 30/611; H10D 62/10; H10D 62/393

(57) ABSTRACT

A semiconductor device comprising, a substrate comprising a cell region, a first well region in the cell region of the substrate, a second well region disposed in the cell region and spaced apart from the first well region in a first direction, a third well region disposed in the cell region and spaced apart from the first well region in a second direction intersecting the first direction, a first gate portion disposed in overlap with a part of the first well region and a part of the third well region, and a second gate portion disposed in overlap with a part of the second well region, wherein the first gate portion and the second gate portion are spaced apart from each other.

### CROSS-REFERENCE TO RELATED APPLICATION

This application claims priority under 35 U.S.C § 119 to Korean Patent Application No. 10-2024-0050120 filed on Apr. 15, 2024, in the Korean Intellectual Property Office, the entire contents of which are hereby incorporated by reference.

### TECHNICAL FIELD

The disclosure relates to a semiconductor device, and more particularly, to a semiconductor device in a planar structure for reducing on-resistance.

### BACKGROUND

The contents set forth in this section merely provide background information on the present embodiments and do not constitute prior art.

Semiconductor devices (e.g., power semiconductors) are on/off switches, and are elements in which current is conducted when in the on state and reverse current is blocked by withstanding reverse voltage up to the breakdown voltage when in the off state. The on-resistance and capacitance that may be generated during the on/off switching operation of a semiconductor device are directly related to the characteristics of the semiconductor device. The on-resistance refers to the resistance between the drain and the source when the gate of a semiconductor device is in the on state. The capacitance may refer to the capacitance between the gate and the drain.

Lowering the on-resistance can improve the efficiency of a semiconductor device. If high integration of a semiconductor device is implemented or a chip with a large area is used to lower the on-resistance, the capacitance may increase. Conversely, if the gate insulating film is made thicker to reduce capacitance, the on-resistance will increase.

Therefore, there has been a need for a semiconductor device structure that can improve the efficiency of the semiconductor device by reducing both the on-resistance and the capacitance.

### SUMMARY

It is an object of the present disclosure to provide a semiconductor device that can reduce both the on-resistance and the capacitance.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

According to some aspects of the disclosure, a semiconductor device comprises, a substrate comprising a cell region, a first well region in the cell region of the substrate, a second well region disposed in the cell region and spaced apart from the first well region in a first direction, a third well region disposed in the cell region and spaced apart from the first well region in a second direction intersecting the first direction, a first gate portion disposed in overlap with a part of the first well region and a part of the third well region, and a second gate portion disposed in overlap with a part of the second well region, wherein the first gate portion and the second gate portion are spaced apart from each other.

According to some aspects, further comprising a field insulating film disposed on the substrate and disposed between the first gate portion and the second gate portion.

According to some aspects, further comprising a gate extension portion disposed on the field insulating film and disposed between the first gate portion and the second gate portion.

According to some aspects, the field insulating film comprises: a first portion surrounding the cell region; and a second portion disposed between the first gate portion and the second gate portion, disposed between the first well region and the second well region, and disposed between the third well region and the second well region.

According to some aspects, the second portion of the field insulating film extends along the first gate portion and the second gate portion, between the first gate portion and the second gate portion.

According to some aspects, further comprising a third gate portion disposed in overlap with a part of the first well region and a part of the third well region and disposed between the first well region and the third well region.

According to some aspects, further comprising an insulating film disposed on each of the first gate portion, the second gate portion, and the gate extension portion.

According to some aspects, comprising: a first channel region being a portion of the first well region and disposed along an edge of the first well region; a second channel region being a portion of the second well region and disposed along an edge of the second well region; and a third channel region being a portion of the third well region and disposed along an edge of the third well region, wherein the first gate portion is disposed on the first channel region, and the second gate portion is disposed on the second channel region and is non-overlapped with the first channel region.

According to some aspects, further comprising a third gate portion disposed on the first well region and the third well region and disposed to overlap the first channel region and the third channel region.

According to some aspects, further comprising an insulating film disposed between the first gate portion and the second gate portion and disposed on the first gate portion and the second gate portion.

According to some aspects, further comprising a third gate portion disposed in overlap with a part of the first well region and a part of the third well region and disposed between the first well region and the third well region.

According to some aspects of the disclosure, a semiconductor device comprises, a substrate comprising a cell region, a first well region in the cell region of the substrate, a second well region disposed in the cell region and spaced apart from the first well region in a first direction, a third well region disposed in the cell region and spaced apart from the first well region in a second direction intersecting the first direction, a first channel region being a portion of the first well region and disposed along an edge of the first well region, a second channel region being a portion of the second well region and disposed along an edge of the second well region, a third channel region being a portion of the third well region and disposed along an edge of the third well region, a first gate portion on the first well region and the first channel region, a second gate portion disposed on the second well region and the second channel region, spaced apart from the first gate portion, and non-overlapped with the first channel region, and a third gate portion disposed on the first well region and the third well region and disposed to overlap the first channel region and the third channel region.

According to some aspects, further comprising: a field insulating film disposed on the substrate and disposed between the first gate portion and the second gate portion; and a gate extension portion disposed on the field insulating film and disposed between the first gate portion and the second gate portion.

According to some aspects, the field insulating film comprises: a first portion surrounding the cell region; and a second portion disposed between the first gate portion and the second gate portion, disposed between the first well region and the second well region, and disposed between the third well region and the second well region, and wherein the second portion of the field insulating film extends along the first gate portion and the second gate portion, between the first gate portion and the second gate portion.

According to some aspects, further comprising an insulating film disposed on each of the first gate portion, the second gate portion, and the gate extension portion.

According to some aspects, the third gate portion is disposed to overlap a doped region between the first channel region and the third channel region.

According to some aspects, further comprising an insulating film disposed between the first gate portion and the second gate portion and disposed on the first gate portion and the second gate portion.

According to some aspects of the disclosure, a semiconductor device comprises, a substrate comprising a cell region, a first well region in the cell region of the substrate, a second well region disposed in the cell region and spaced apart from the first well region in a first direction, a first gate portion on the first well region, a second gate portion on the second well region, a field insulating film disposed on the substrate and disposed between the first gate portion and the second gate portion, and a gate extension portion disposed on the field insulating film and disposed between the first gate portion and the second gate portion.

According to some aspects, further comprising: a third well region disposed in the cell region and spaced apart from the first well region along a second direction intersecting the first direction; and a third gate portion disposed on the first well region and the third well region.

According to some aspects, the field insulating film comprises: a first portion surrounding the cell region; and a second portion disposed between the first gate portion and the second gate portion, disposed between the first well region and the second well region, and disposed between the third well region and the second well region, and wherein the second portion of the field insulating film extends along the first gate portion and the second gate portion, between the first gate portion and the second gate portion.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

The semiconductor device of the present disclosure can improve the efficiency thereof by reducing the on-resistance by increasing the area of the channel region and reducing the capacitance by separating the gates from each other.

In addition to the contents described above, specific effects of the present disclosure will be described together while describing the following specific details for carrying out the present disclosure.

### BRIEF DESCRIPTION OF THE DRAWINGS

FIG. 1 is a plan view for describing a semiconductor device in accordance with some embodiments of the present disclosure.

FIGS. 2 and 3 are enlarged views of the region K in FIG.

FIG. 4 is a cross-sectional view taken along line A-A of FIGS. 2 and 3.

FIG. 5 is a cross-sectional view taken along line B-B of FIGS. 2 and 3.

FIGS. 6 and 7 are enlarged views of the region K in FIG. 1.

FIG. 8 is a cross-sectional view taken along line C-C of FIGS. 6 and 7.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

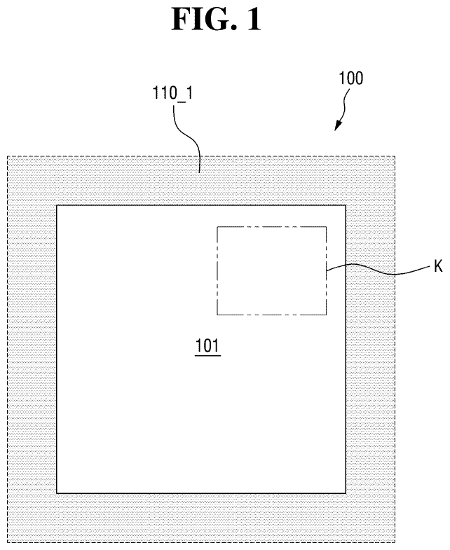

Hereinafter, a semiconductor device in accordance with some embodiments of the present disclosure will be described with reference to FIGS. 1 to 5.

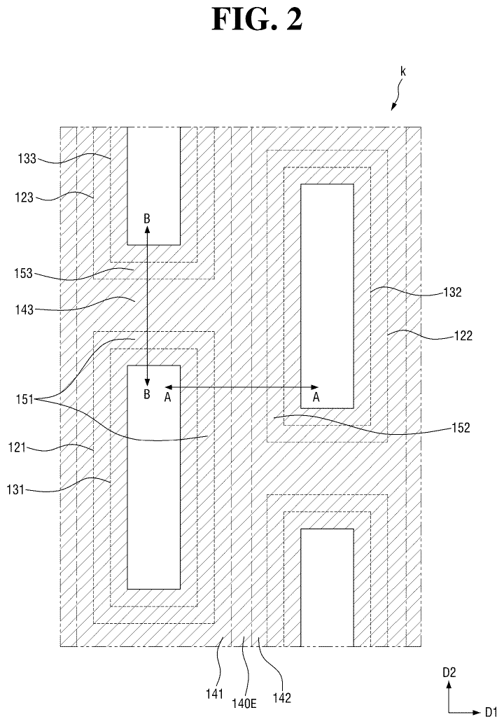

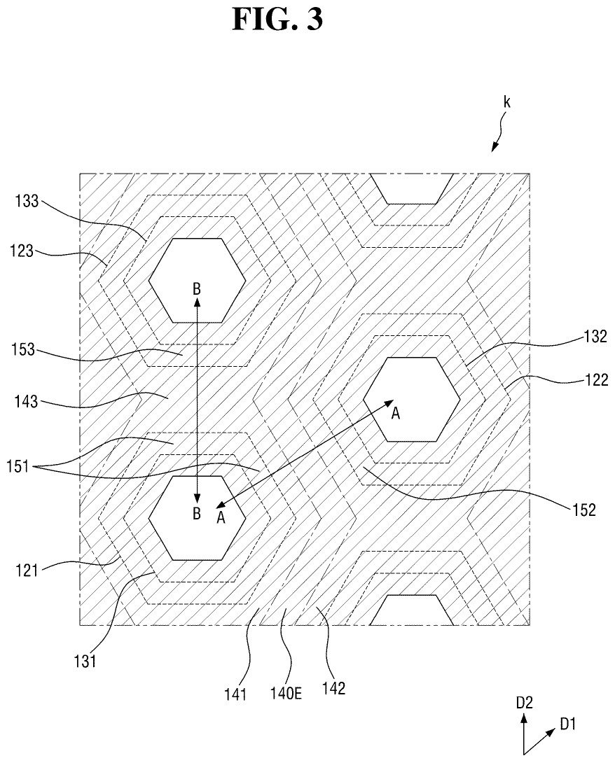

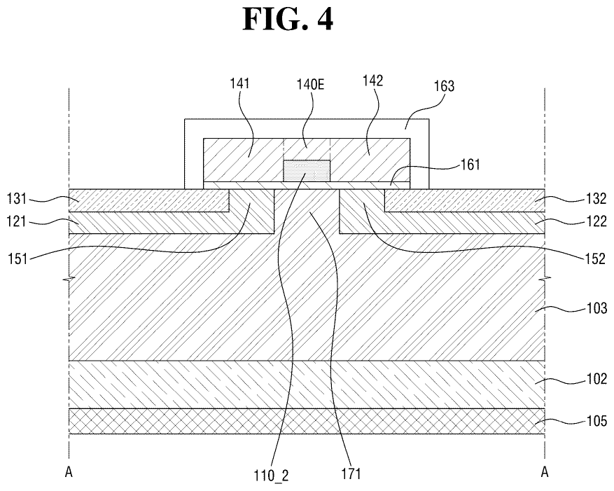

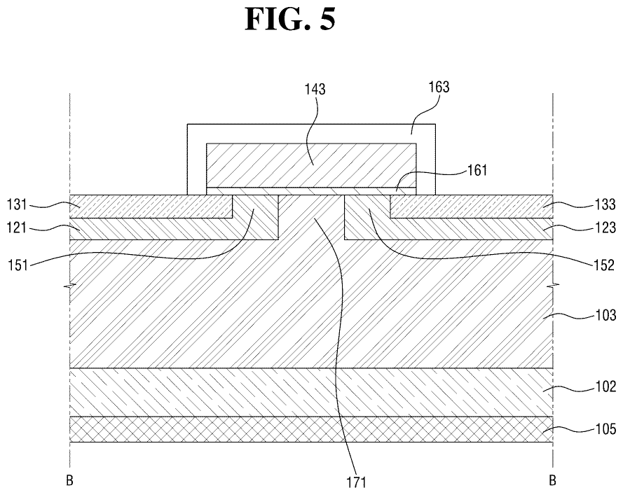

FIG. 1 is a plan view for describing a semiconductor device in accordance with some embodiments of the present disclosure. FIGS. 2 and 3 are enlarged views of the region K in FIG. 1. FIG. 4 is a cross-sectional view taken along line A-A of FIGS. 2 and 3. FIG. 5 is a cross-sectional view taken along line B-B of FIGS. 2 and 3.

Referring to FIG. 1, a semiconductor device 100 in accordance with some embodiments of the present disclosure may include a cell region 101 and a first portion 110_1 of a field insulating film. The cell region 101 and the first portion 110_1 of the field insulating film may be disposed on a substrate (102 in FIG. 3) of the semiconductor device 100.

The first portion 110_1 of the field insulating film may be disposed to surround the cell region 101.

Referring to FIGS. 1, 2, and 3, the cell region 101 of the semiconductor device 100 may include a first well region 121, a second well region 122, a third well region 123, a first source region 131, a second source region 132, a third source region 133, a first gate portion 141, a second gate portion 142, a third gate portion 143, a gate extension portion 140E, a first channel region 151, a second channel region 152, and a third channel region 153.

In FIGS. 2 and 3, other components (e.g., the insulating film, etc.) are omitted for clarity of illustration.

The first well region 121, the second well region 122, and the third well region 123 may be disposed in the cell region 101 of the substrate. The first well region 121, the second well region 122, and the third well region 123 are illustrated as being disposed in a rectangular shape in FIG. 2, but are not limited thereto. The first well region 121, the second well region 122, and the third well region 123 may be disposed in a hexagonal shape, for example, as shown in FIG. 3. The first well region 121, the second well region 122, and the third well region 123 may have, for example, a closed shape.

The second well region 122 may be spaced apart from the first well region 121 in a first direction D1. The third well region 123 may be spaced apart from the first well region 121 in a second direction D2. The first direction D1 and the second direction D2 may be directions intersecting with each other. The first well region 121, the second well region 122, and the third well region 123 may include first-type impurities (e.g., p-type impurities).

The first source region 131 may be disposed to be smaller than the first well region 121 within the first well region 121. The first source region 131 may be disposed to overlap a part of the first well region 121. The first source region 131 may be disposed in substantially the same shape as the first well region 121.

The second source region 132 may be disposed to be smaller than the second well region 122 within the second well region 122. The second source region 132 may be disposed to overlap a part of the second well region 122. The second source region 132 may be disposed in substantially the same shape as the second well region 122. The second source region 132 may be spaced apart from the first source region 131 in the first direction D1.

The third source region 133 may be disposed to be smaller than the third well region 123 within the third well region 123. The third source region 133 may be disposed to overlap a part of the third well region 123. The third source region 133 may be disposed in substantially the same shape as the third well region 123. The third source region 133 may be spaced apart from the first source region 131 in the second direction D2.

The first source region 131, the second source region 132, and the third source region 133 may include second-type impurities (e.g., n-type impurities). The first-type and the second-type may be different from each other.

The first channel region 151 may be a part of the first well region 121 exposed by the first source region 131. The first channel region 151 may be disposed along the edge of the first well region 121. The first channel region 151 is a portion of the first well region 121 and may be disposed to surround the first source region 131. The first channel region 151 may be disposed in substantially the same shape as the first well region 121.

The second channel region 152 may be a part of the second well region 122 exposed by the second source region 132. The second channel region 152 may be disposed along the edge of the second well region 122. The second channel region 152 is a portion of the second well region 122 and may be disposed to surround the second source region 132. The second channel region 152 may be disposed in substantially the same shape as the second well region 122.

The third channel region 153 may be a part of the third well region 123 exposed by the third source region 133. The third channel region 153 may be disposed along the edge of the third well region 123. The third channel region 153 is a portion of the third well region 123 and may be disposed to surround the third source region 133. The third channel region 153 may be disposed in substantially the same shape as the third well region 123.

The gate electrodes 141, 142, 143, and 140E may be disposed on the well regions 121, 122, and 123, the source regions 131, 132, and 133, and the channel regions 151, 152, and 153.

The first gate portion 141 may be disposed in overlap with a part of the first well region 121 and a part of the third well region 123. The first gate portion 141 may be disposed between the first well region 121 and the second well region 122, and may be disposed between the third well region 123 and the second well region 122. The first gate portion 141 may be disposed in overlap with a part of the first source region 131 and a part of the third source region 133. The first gate portion 141 may be disposed in overlap with a part of the first channel region 151 and a part of the third channel region 153. The first gate portion 141 may be non-overlapped with the second source region 132. The first gate portion 141 may be non-overlapped with the second channel region 152.

The second gate portion 142 may be disposed in overlap with a part of the second well region 122. The second gate portion 142 may be disposed between the first well region 121 and the second well region 122, and may be disposed between the third well region 123 and the second well region 122. The second gate portion 142 may be disposed in overlap with a part of the second source region 132. The second gate portion 142 may be disposed in overlap with a part of the second channel region 152. The second gate portion 142 may be non-overlapped with the first source region 131 and the third source region 133. The second gate portion 142 may be non-overlapped with the first channel region 151 and the third channel region 153.

The third gate portion 143 may be disposed in overlap with a part of the first well region 121 and a part of the third well region 123. The third gate portion 143 may be disposed between the first well region 121 and the third well region 123. The third gate portion 143 may be disposed in overlap with a part of the first source region 131 and a part of the third source region 133. The third gate portion 143 may be disposed in overlap with a part of the first channel region 151 and a part of the third channel region 153. The third gate portion 143 may be non-overlapped with the second channel region 152.

The gate extension portion 140E may be disposed between the first gate portion 141 and the second gate portion 142. The gate extension portion 140E may be disposed on the second portion (110_2 in FIG. 4) of the field insulating film. This will be described later.

The gate electrodes 141, 142, 143, and 140E may include at least one of, for example, TiN, WN, TaN, Ru, TiC, TaC, Ti, Ag, Al, TiAl, TiAlN, TiAlC, TaCN, TaSiN, Mn, Zr, W, and Al. Alternatively, the gate electrodes 141, 142, 143, and 140E may consist of Si, SiGe, Poly-Si, etc., instead of metal.

Referring to FIGS. 1, 2, 3, and 4, the semiconductor device 100 may include a substrate 102, a drift region 103, a drain region 105, a doped region 171, a second portion 110_2 of the field insulating film, a gate insulating film 161, and an insulating film 163.

The substrate 102 may be, for example, bulk silicon, silicon carbide, or silicon-on-insulator (SOI). Alternatively, the substrate 102 may include other materials, for example, silicon germanium, indium antimonide, lead telluride, indium arsenide, indium phosphide, gallium arsenide, or gallium antimonide.

The drift region 103 may be disposed on the substrate 102. The drift region 103 may include the second-type impurity (e.g., the n-type impurity).

The doped region 171 may be a partial region of the drift region 103. The doped region 171 may be disposed between the first channel region 151 and the second channel region 152. The doped region 171 may include the second-type impurity (e.g., the n-type impurity).

The drain region 105 may be disposed beneath the substrate 102.

The first well region 121 and the second well region 122 may be disposed on the substrate 102. The first source region 131 may be disposed on the first well region 121. The second source region 132 may be disposed on the second well region 122. The first channel region 151 may be a partial region of the first well region 121 and may be disposed to overlap the first source region 131 in the horizontal direction. The second channel region 152 may be a partial region of the second well region 122 and may be disposed to overlap the second source region 132 in the horizontal direction.

The gate insulating film 161 may be disposed on the substrate 102. The gate insulating film 161 may be disposed on the first channel region 151, the second channel region 152, the first source region 131, and the second source region 132. The gate insulating film 161 may be disposed to overlap the first gate portion 141, the second gate portion 142, and the second portion 110_2 of the field insulating film.

The first gate portion 141 may be disposed on a part of the first well region 121. The first gate portion 141 may be disposed on the first channel region 151. The first gate portion 141 may be disposed on a part of the first source region 131. The second gate portion 142 may be disposed on a part of the second well region 122. The second gate portion 142 may be disposed on a part of the second source region 132. The second gate portion 142 may be disposed on the second channel region 152.

The first gate portion 141 may be disposed to be non-overlapped with the second channel region 152. The second gate portion 142 may be disposed to be non-overlapped with the first channel region 151. The first gate portion 141 and the second gate portion 142 may be spaced apart from each other.

The second portion 110_2 of the field insulating film may be disposed between the first gate portion 141 and the second gate portion 142. The second portion 110_2 of the field insulating film may extend along the first gate portion 141 and the second gate portion 142, between the first gate portion 141 and the second gate portion 142. The second portion 110_2 of the field insulating film may be disposed between the first well region 121 and the second well region 122. The second portion 110_2 of the field insulating film may extend from the first portion 110_1 of the field insulating film. The second portion 110_2 of the field insulating film may be disposed between the second well region 122 and the third well region 123.

The gate extension portion 140E may be disposed on the second portion 110_2 of the field insulating film. The gate extension portion 140E may be disposed between the first gate portion 141 and the second gate portion 142.

The insulating film 163 may be disposed to surround the first gate portion 141, the second gate portion 142, the gate extension part 140E, and the second portion 110_2 of the field insulating film. The insulating film 163 may be disposed on each of the first gate portion 141, the second gate portion 142, and the gate extension portion 140E. The insulating film 163 may be, for example, pre-metal dielectric (PMD).

The semiconductor device 100 in accordance with some embodiments of the present disclosure can reduce both the on-resistance and capacitance of the semiconductor device 100 and further secure a process margin by including the first gate portion 141 and the second gate portion 142 that are spaced apart from each other, including the second portion 110_2 of the field insulating film disposed between the first gate portion 141 and the second gate portion 142, and including the gate extension portion 140E disposed on the second portion 110_2 of the field insulating film between the first gate portion 141 and the second gate portion 142. In addition, the semiconductor device 100 in accordance with some embodiments of the present disclosure can reduce the on-resistance by increasing the area of the channel region by including the well regions 121, 122, and 123 and the channel regions 151, 152, and 153 that have a closed structure. For example, if the area of the channel region increases, the JFET of the doped region 171 may increase, which may in turn increase the capacitance between the gate electrode and the drain region, but the semiconductor device 100 in accordance with some embodiments of the present disclosure can reduce the capacitance by separating the first gate portion 141 and the second gate portion 142 apart from each other, and disposing the second portion 110_2 of the field insulating film between the first gate portion 141 and the second gate portion 142. In addition, a process margin can be secured by disposing the gate extension portion 140E on the second portion 110_2 of the field insulating film, taking into account that conduction in the channel region may not be possible if the first gate portion 141 and the second gate portion 142 are separated completely.

Referring to FIGS. 1, 2, 3, and 5, the third gate portion 143 may be disposed on a part of the first well region 121 and a part of the third well region 123. The third gate portion 143 may be disposed on the first channel region 151 and the third channel region 153. The third gate portion 143 may be disposed on the doped region 171.

In the following, a semiconductor device in accordance with some embodiments of the present disclosure will be described with reference to FIGS. 1 and 5 to 8. For clarity of description, any description that overlaps with what has been described will be omitted.

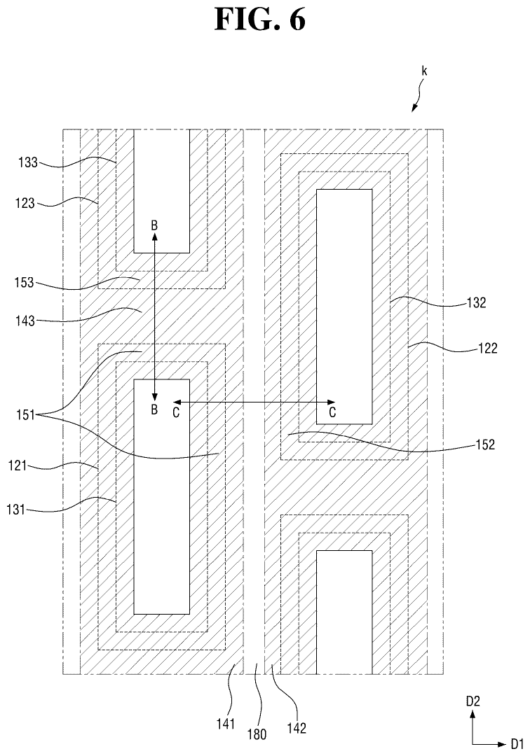

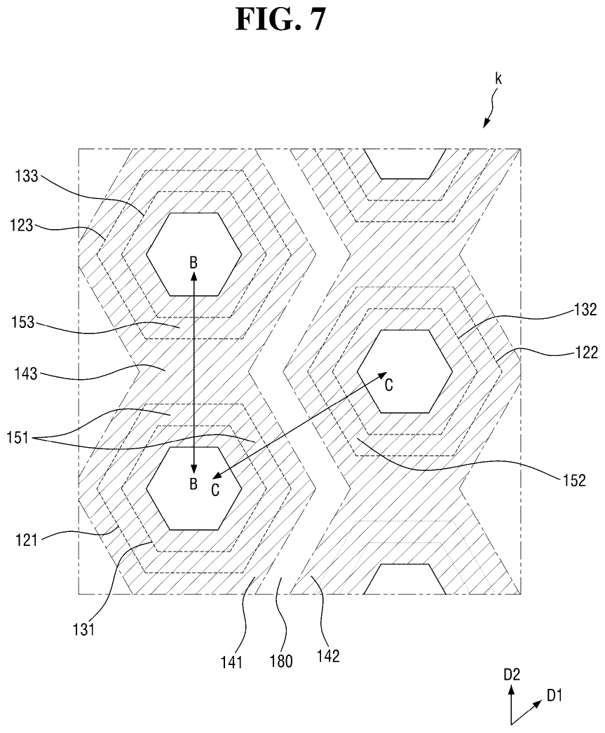

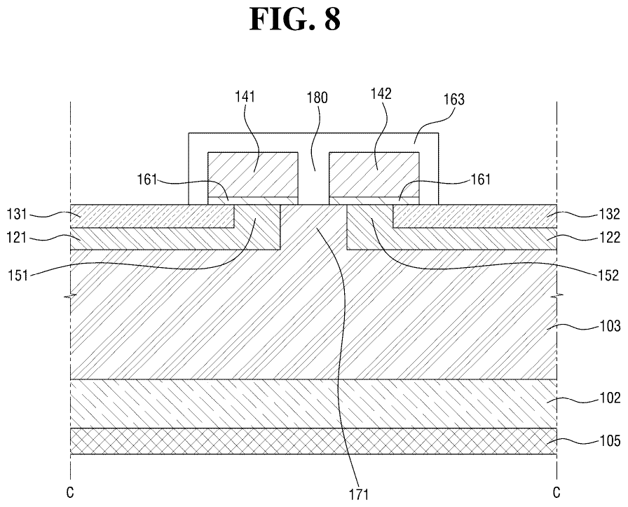

FIGS. 6 and 7 are enlarged views of the region K in FIG. 1. FIG. 8 is a cross-sectional view taken along line C-C of FIGS. 6 and 7. In FIGS. 6 and 7, other components (e.g., the insulating film, etc.) are omitted for clarity of illustration.

Referring to FIGS. 1, 6, and 7, the semiconductor device 100 of some embodiments of the present disclosure may include a spaced-apart region 180. The spaced-apart region 180 may be disposed between the first gate portion 141 and the second gate portion 142. The spaced-apart region 180 may extend along the first gate portion 141 and the second gate portion 142.

The cross-sectional view taken along line B-B in FIGS. 6 and 7 is the same as FIG. 5. The third gate portion 143 may not include the spaced-apart region 180.

Referring to FIGS. 1, 6, 7, and 8, the spaced-apart region 180 may be filled with the insulating film 163. A part of the insulating film 163 disposed in the spaced-apart region 180 may be disposed between the first gate portion 141 and the second gate portion 142. By the part of the insulating film 163 disposed in the spaced-apart region 180, the first gate portion 141 and the second gate portion 142 may be spaced apart and insulated from each other.

The insulating film 163 may be disposed between the first gate portion 141 and the second gate portion 142 and may be disposed on each of the first gate portion 141 and the second gate portion 142.

The semiconductor device 100 in accordance with some embodiments of the present disclosure can reduce the on-resistance by increasing the area of the channel region by including the well regions 121, 122, and 123 and the channel regions 151, 152, and 153 that have a closed structure. On the other hand, if the channel region increases, the capacitance between the gate electrode and the drain region increases, but the semiconductor device 100 in accordance with some embodiments of the present disclosure can reduce the capacitance between the gate electrode and the drain region by separating the first gate portion 141 and the second gate portion 142 by the part of the insulating film 163 disposed in the spaced-apart region 180.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor device comprising:
a substrate comprising a cell region;
a first well region in the cell region of the substrate;
a second well region disposed in the cell region and spaced apart from the first well region in a first direction;
a third well region disposed in the cell region and spaced apart from the first well region in a second direction intersecting the first direction;
a first gate portion disposed in overlap with a part of the first well region and a part of the third well region; and
a second gate portion disposed in overlap with a part of the second well region,
wherein the first gate portion and the second gate portion are spaced apart from each other.

2. The semiconductor device of claim 1, further comprising a field insulating film disposed on the substrate and disposed between the first gate portion and the second gate portion.

3. The semiconductor device of claim 2, further comprising a gate extension portion disposed on the field insulating film and disposed between the first gate portion and the second gate portion.

4. The semiconductor device of claim 3, wherein the field insulating film comprises:
a first portion surrounding the cell region; and
a second portion disposed between the first gate portion and the second gate portion, disposed between the first well region and the second well region, and disposed between the third well region and the second well region.

5. The semiconductor device of claim 4, wherein the second portion of the field insulating film extends along the first gate portion and the second gate portion, between the first gate portion and the second gate portion.

6. The semiconductor device of claim 2, further comprising a third gate portion disposed in overlap with a part of the first well region and a part of the third well region and disposed between the first well region and the third well region.

7. The semiconductor device of claim 2, further comprising an insulating film disposed on each of the first gate portion, the second gate portion, and the gate extension portion.

8. The semiconductor device of claim 1, comprising:
a first channel region being a portion of the first well region and disposed along an edge of the first well region;
a second channel region being a portion of the second well region and disposed along an edge of the second well region; and
a third channel region being a portion of the third well region and disposed along an edge of the third well region,
wherein the first gate portion is disposed on the first channel region, and
the second gate portion is disposed on the second channel region and is non-overlapped with the first channel region.

9. The semiconductor device of claim 8, further comprising a third gate portion disposed on the first well region and the third well region and disposed to overlap the first channel region and the third channel region.

10. The semiconductor device of claim 1, further comprising an insulating film disposed between the first gate portion and the second gate portion and disposed on the first gate portion and the second gate portion.

11. The semiconductor device of claim 10, further comprising a third gate portion disposed in overlap with a part of the first well region and a part of the third well region and disposed between the first well region and the third well region.

12. A semiconductor device comprising:
a substrate comprising a cell region;
a first well region in the cell region of the substrate;
a second well region disposed in the cell region and spaced apart from the first well region in a first direction;
a third well region disposed in the cell region and spaced apart from the first well region in a second direction intersecting the first direction;
a first channel region being a portion of the first well region and disposed along an edge of the first well region;
a second channel region being a portion of the second well region and disposed along an edge of the second well region;
a third channel region being a portion of the third well region and disposed along an edge of the third well region;
a first gate portion on the first well region and the first channel region;
a second gate portion disposed on the second well region and the second channel region, spaced apart from the first gate portion, and non-overlapped with the first channel region; and
a third gate portion disposed on the first well region and the third well region and disposed to overlap the first channel region and the third channel region.

13. The semiconductor device of claim 12, further comprising:
a field insulating film disposed on the substrate and disposed between the first gate portion and the second gate portion; and
a gate extension portion disposed on the field insulating film and disposed between the first gate portion and the second gate portion.

14. The semiconductor device of claim 13, wherein the field insulating film comprises:
a first portion surrounding the cell region; and
a second portion disposed between the first gate portion and the second gate portion, disposed between the first well region and the second well region, and disposed between the third well region and the second well region, and
wherein the second portion of the field insulating film extends along the first gate portion and the second gate portion, between the first gate portion and the second gate portion.

15. The semiconductor device of claim 13, further comprising an insulating film disposed on each of the first gate portion, the second gate portion, and the gate extension portion.

16. The semiconductor device of claim 13, wherein the third gate portion is disposed to overlap a doped region between the first channel region and the third channel region.

17. The semiconductor device of claim 12, further comprising an insulating film disposed between the first gate portion and the second gate portion and disposed on the first gate portion and the second gate portion.

18. A semiconductor device comprising:
a substrate comprising a cell region;
a first well region in the cell region of the substrate;
a second well region disposed in the cell region and spaced apart from the first well region in a first direction;
a first gate portion on the first well region;
a second gate portion on the second well region;
a field insulating film disposed on the substrate and disposed between the first gate portion and the second gate portion; and
a gate extension portion disposed on the field insulating film and disposed between the first gate portion and the second gate portion.

19. The semiconductor device of claim 18, further comprising:
a third well region disposed in the cell region and spaced apart from the first well region along a second direction intersecting the first direction; and
a third gate portion disposed on the first well region and the third well region.

20. The semiconductor device of claim 19, wherein the field insulating film comprises:
a first portion surrounding the cell region; and
a second portion disposed between the first gate portion and the second gate portion, disposed between the first well region and the second well region, and disposed between the third well region and the second well region, and
wherein the second portion of the field insulating film extends along the first gate portion and the second gate portion, between the first gate portion and the second gate portion.
